(19) United States
(12) Patent Application Publication
(10) Pub. No.: US 2016/0359296 A1
(43) Pub. Date: Dec. 8, 2016

(54) REFLECTOR AND A LASER DIODE ASSEMBLY USING SAME

(71) Applicant: Lumentum Operations LLC, Milpitas, CA (US)

(72) Inventors: Vincent V. WONG, Los Altos, CA (US); James Yonghong Guo, Union City, CA (US); Kong Weng Lee, San Jose, CA (US); Jack Xu, Milpitas, CA (US)

(21) Appl. No.: 14/731,501

(22) Filed: Jun. 5, 2015

(51) Int. Cl. H01S 5/022

(52) U.S. Cl. CPC H01S 5/02292

(57) ABSTRACT

A laser diode assembly is disclosed, in which a transmissive reflector is used to redirect the laser beam upwards or to turn or rotate the laser beam. The reflector has at least one Brewster transmissive surface and at least one total internal reflection surface. Several total internal reflection surfaces rotated with respect to one another may be used in a single reflector to redirect and rotate the laser diode beam.

### TECHNICAL FIELD

The present disclosure relates to optical components and assemblies, and in particular to reflectors and laser diode assemblies using reflectors to redirect emitted optical beams.

### BACKGROUND

Laser diodes are efficient, bright sources of coherent light in near infrared and visible parts of optical spectrum. Edge emitting laser diodes have found widespread application in technical areas ranging from compact disk readers to free-space laser and fiber laser pump sources. Laser diodes have also been used for illumination, marking, printing, ranging, etc.

An output light field of a typical edge-emitting laser diode is anamorphic. The laser beam is usually more divergent in vertical direction, that is, a direction perpendicular to the plane of the laser diode chip, while being less divergent in a horizontal direction. When an edge-emitting laser diode chip is mounted flat on a planar surface such as a printed circuit board (PCB), a quickly diverging laser beam may become clipped by the PCB, because the bigger divergence is perpendicular to the PCB. To alleviate this problem, the laser diode may be mounted vertically on a vertical submount affixed to the PCB. However, the vertical mounting method is rather inconvenient for mass production.

Another common issue with edge-emitting laser diodes is that a laser diode beam propagates along the PCB, while in many applications a desired light direction is away from the PCB, often perpendicular to the PCB. This problem could also be solved by disposing the laser chip vertically, emitting edge up, but this is even less convenient than disposing the laser diode chip vertically and sideways. Furthermore, the laser diode chip may be simply too long to be disposed vertically, emitting edge up. One can redirect the laser diode emission by providing a 45-degree turning mirror proximate the emitting edge of a horizontal laser diode chip. The 45-degree turning mirror would reflect the laser beam upwards and away from the PCB. However, the 45-degree turning mirror usually needs to be coated with a durable and reliable optical coating, in view of close proximity of the 45-degree turning mirror to the emitting edge of the laser diode chip. This may raise manufacturing costs of laser diode assembly. Yet another prior-art solution is to polish the emitting edge of the laser diode chip at 45°, so that the output beam may be reflected upwards. However, this method is not universal, since some laser diodes require the output surface to be perpendicular to the laser beam, to form an optical cavity. Furthermore, angle-polishing laser diode chips would inevitably cause some of the laser diode chips to be damaged, lowering the overall yield of the laser diode assemblies.

Prior-art solutions described above are lacking a simple and inexpensive method of redirecting and/or rotating the laser beam emitted by a side-emitting laser diode chip.

### SUMMARY

One cost factor of adding a reflector to a side-emitting laser diode chip for redirecting the laser beam is that a miniature reflector placed in front of the laser diode chip typically needs to be coated with an optical coating to transmit and reflect the laser beam efficiently. According to the present disclosure, the need for an optical coating may be reduced or alleviated by utilizing total internal reflection (TIR), which may occur from inside of an optically dense transparent material. A Brewster's angle may be utilized to reduce optical losses associated with transmitting the optical beam between the optically dense transparent material and surrounding medium, such as air.

In accordance with an aspect of the disclosure, there is provided a laser diode assembly comprising:

a mount;

a laser diode chip comprising a bottom surface on the mount, an end facet for emitting a laser beam comprising a direction of propagation, a fast divergence axis, and a slow divergence axis, mutually perpendicular to each other;

a reflector on the mount, for receiving and redirecting the laser beam, the reflector comprising an input face, a first reflector face, and an output face disposed consecutively in an optical path of the laser beam, wherein the optical path is defined by orientation of the input face, the first reflector face, and the output face;

wherein at least one of the input and output faces is disposed at a Brewster's angle with respect to the laser beam for transmitting the laser beam;

wherein the first reflector face is disposed for receiving the laser beam transmitted through the first face and for reflecting the laser beam by TIR; and

wherein the output face is configured to transmit the laser beam reflected from the first reflector face.

In one exemplary embodiment, the first reflector face is disposed to reflect the laser beam impinging thereon in a direction away and upwards from the mount, the laser diode assembly further comprising a second reflector face disposed in the optical path of the laser beam between the first reflector face and the output face, for reflecting the laser beam impinging on the second reflector face by TIR.

In accordance with the disclosure, there is further provided a reflector comprising:

a first prismatic segment comprising an input Brewster face for transmitting an optical beam impinging thereon, and a first reflector face for reflecting, by TIR, the optical beam transmitted through the input face; and

a second prismatic segment extending from the first prismatic segment, the second prismatic segment comprising a second reflector face for reflecting, by TIR, the optical beam reflected from the first reflector face;

wherein the second prismatic segment forms a 90° rotation angle with respect to the first prismatic segment about an optical axis between the first and second reflector faces.

In accordance with another aspect of the disclosure, there is further provided a method for directing light emitted by an edge-emitting laser diode chip, the method comprising:

disposing in an optical path of the optical beam a reflector comprising an input Brewster face for transmitting the optical beam impinging thereon, a first reflector face, a second reflector face, and an output face for transmitting the optical beam reflected from the second reflector face;

transmitting the optical beam through the input Brewster face; reflecting, by TIR, the optical beam transmitted through the input face with the first reflector face; reflecting, by TIR, the optical beam reflected from the first reflector face with the second reflector face; and transmitting the optical beam reflected from the second reflector face through the output face;

wherein the second reflector face is disposed with respect to the first reflector face so that planes of incidence of the optical beam on the first and second reflector faces are substantially perpendicular to each other.

In one exemplary embodiment, the reflector further includes a third reflector face disposed in an optical path of the optical beam between the input face and the first reflector, for reflecting the optical beam impinging on the third reflector face by TIR.

### BRIEF DESCRIPTION OF THE DRAWINGS

Exemplary embodiments will now be described in conjunction with the drawings, in which:

FIGS. 1A and 1B illustrate plan and side elevational views, respectively, of an embodiment of a laser diode assembly including a reflector for redirecting a vertically polarized laser beam, the reflector having an input Brewster face;

FIG. 1C illustrates divergence axes and a direction of propagation of the laser beam shown in FIGS. 1A and 1B;

FIGS. 2A and 2B illustrate plan and side elevational views, respectively, of an embodiment of the laser diode assembly of FIGS. 1A and 1B, in which the reflector has both input and output Brewster faces;

FIG. 3A illustrates a plan views of an embodiment of a laser diode assembly of FIGS. 1A and 1B, in which the reflector includes two reflecting faces for rotating the laser beam;

FIGS. 3B and 3C illustrate side elevational views of the laser diode assembly of FIG. 3A taken along directions B-B and C-C, respectively, shown in FIG. 3A;

FIGS. 4A and 4B illustrate side elevational and frontal views of a light cone emitted by a laser diode assembly including a side-emitting laser diode chip;

FIGS. 5A and 5B illustrate side elevational and frontal views of a light cone emitted by a side-emitting laser diode chip and rotated by the reflector of FIGS. 3A-3C;

FIGS. 6A and 6B illustrate plan and side elevational views, respectively, of an embodiment of a laser diode assembly including a reflector for redirecting a horizontally polarized laser beam;

FIG. 7A illustrates a plan views of an embodiment of a laser diode assembly of FIGS. 6A and 6B, in which the reflector includes two reflecting surfaces for rotating the laser beam;

FIGS. 7B and 7C illustrate side elevational views of the laser diode assembly of FIG. 7A taken along directions B-B and C-C, respectively, shown in FIG. 7A;

FIG. 8 illustrates a plan-view ray tracing diagram of a prismatic reflector segment for turning a horizontally polarized laser beam by 90°;

FIG. 9 illustrates a side-view ray tracing diagram of a prismatic reflector segment for turning a vertically polarized laser beam by 90°;

FIG. 10A illustrates a three-dimensional view ray tracing diagram of a reflector comprising two prismatic segments rotated with respect to each other;

FIG. 10B illustrates a three-dimensional view ray tracing diagram of a reflector comprising three prismatic segments rotated with respect to each other;

FIG. 11 illustrates a three-dimensional rendered view of a packaged laser diode assembly; and

FIG. 12 illustrates a flow chart of a method for directing an optical beam emitted by an edge-emitting laser diode chip.

### DETAILED DESCRIPTION

While the present teachings are described in conjunction with various embodiments and examples, it is not intended that the present teachings be limited to such embodiments. On the contrary, the present teachings encompass various alternatives and equivalents, as will be appreciated by those of skill in the art. In Figures, similar reference numerals refer to similar elements.

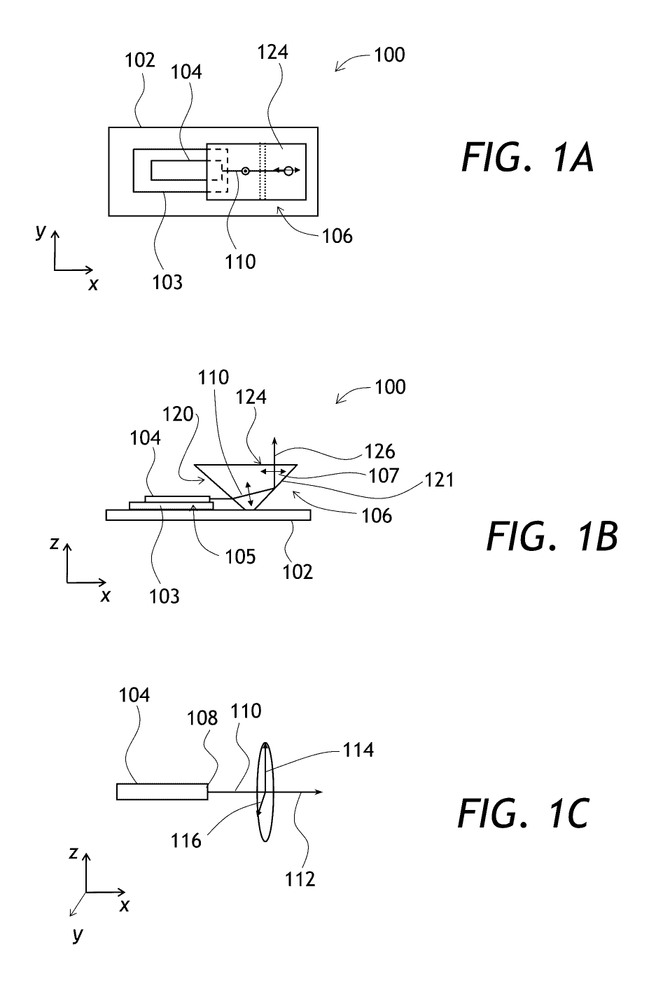

Referring to FIGS. 1A, 1B, and 1C, a laser diode assembly 100 (FIGS. 1A, 1B) may include a mount 102, a laser diode chip 104 on an optional submount 103 attached to the mount 102. The laser diode chip 104 may be configured to emit a laser beam 110. A reflector 106 may be disposed on the mount 102 for receiving and redirecting the laser beam 110. The mount 102 may include a printed circuit board (PCB), a dedicated metal or ceramic plate, etc. The submount 103 may be integrated into the mount 102. The laser diode chip 104 may include a substrate having a bottom surface or layer 105 supporting a thin layer structure, not shown. The thin layer structure may include a light-emitting planar active layer between p- and n-layers. As known to a person skilled in the art, thin-film layers comprising the laser diode 104 typically extend parallel to the bottom surface 105. The bottom surface 105 and the active layer of the laser diode chip 104 are shown disposed in XY plane (FIG. 1A).

The laser diode chip 104 may be mounted by affixing, e.g. soldering, its bottom surface 105 to the submount 103 to provide mechanical support, an electrical contact, heat removal, etc. The laser beam 110 emitted from an end facet 108 (FIG. 1C) of the laser diode chip 104 has a direction of propagation 112, a fast divergence axis 114, and a slow divergence axis 116, mutually perpendicular to each other. In the embodiment shown in FIGS. 1A and 1B, the laser beam 110 emitted by the laser diode chip 104 is polarized vertically with respect to the bottom surface 105 and the mount 102, that is, in XZ plane (FIG. 1B). The polarization of the laser beam 110 is denoted by arrows 107.

The reflector 106 may include an input face 120, a first reflector face 121, and an output face 124. Together, the input face 120, the first reflector face 121, and the output face 124 define an optical path 126 of the laser beam 110, which impinges in sequence on the input face 120, the first reflector face 121, and finally on the output face 124. The first reflector face 121 may be disposed for receiving the laser beam 110, which has been transmitted through the input face 120 and refracted due to the difference in refractive index between the surrounding atmosphere, e.g. air, and the reflector 106, and for redirecting the laser beam 110 by TIR from the first reflector face 121 to the output face 124. The output face 124 may be configured to transmit the laser beam 110 reflected from the first reflector face 121 outside of the reflector 106. As known to a person skilled in the art, the TIR condition may be written as

sin(θᵢ)≧1/n (1)

where θ, is angle of incidence of a ray of the laser beam 110 onto the first reflector face 121, and n is the refractive index of the reflector 106 relative to that of the surrounding medium, such as air. For the laser beam 110 to be reflected by TIR, each ray of the laser beam 110 should satisfy the condition (1). In practical terms, only rays within a pre-defined solid angle e.g. +−10 degrees horizontal, +−20 degrees vertical, need to satisfy the condition (1).

The input face 120, the first reflector face 121, and the output face 124 are shown in FIG. 1B disposed at an angle, for example: an acute angle, to each other and perpendicular to a same plane, for example XZ plane. Thus, the input face 120, the first reflector face 121, and the output face 124 may form a prismatic element, for example a triangular prismatic element. The faces 120, 121, and 124 may also be disposed at angles other than shown, and may be not perpendicular to a same plane, so as to form a pyramid, for example. One may select the angles of the faces 120, 121, and 124, as well as the index of refraction of the prismatic element, such that the laser beam 110 exiting from the output face 124 forms a pre-defined angle with the laser beam 110 impinging on the input face 120, for example 90° angle. This configuration may be used to direct the laser beam 110 up and away from the mount 102, for example in a direction perpendicular to the mount 102, as shown in FIG. 1B. The laser beam 110 may be further shaped, focused, etc., by optical elements (not shown) above the laser diode assembly 100.

In the reflector 106 of FIGS. 1A and 1B, the input face 120 may be tilted at a Brewster's angle with respect to the laser beam 110 for reducing transmission loss of the laser beam 110 entering the reflector 106. As known to a person skilled in the art, the Brewster's angle condition may be represented as

tan(θᵢ)=1/n (2)

where θ, is angle of incidence of a ray of the laser beam 110 onto the input face 120, and n is the refractive index of the reflector 106 relative to that of the surrounding medium, such as air.

Due to the Brewster's angle for the impinging p-polarized laser beam 110 represented by condition (1), the input face 120 needs not be coated with an antireflection (AR) coating. The laser beam 110 is reflected from the first reflector face 121 by TIR when condition (1) above is satisfied; therefore, the first reflector face 121 also needs not be coated with a high reflector coating. The output face 124 may be optionally coated with an AR coating to reduce transmission loss. At least one of the input 120 and output 124 faces of the reflector 106 may be disposed at a Brewster's angle, so it needs not be AR coated.

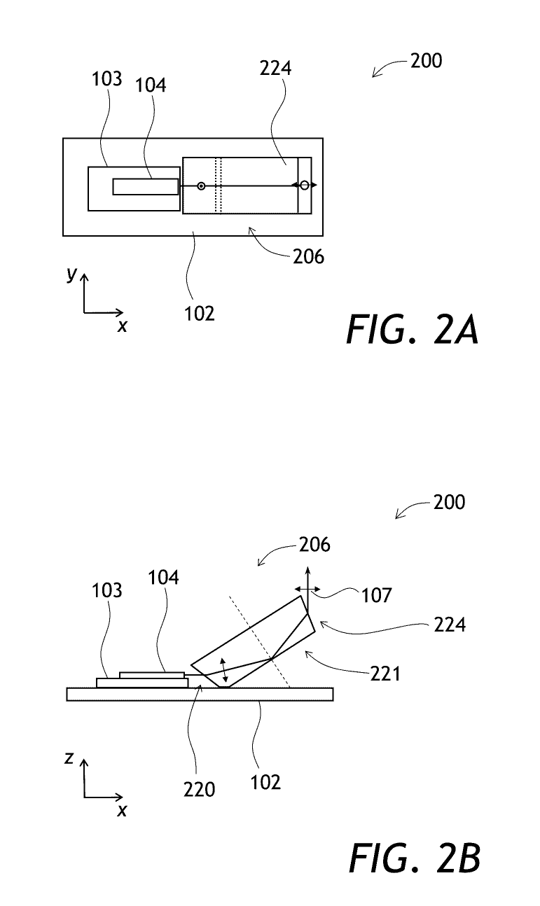

Turning to FIGS. 2A and 2B with further reference to FIGS. 1A-1C, a laser diode chip assembly 200 includes a symmetrical prismatic reflector 206 instead of the reflector 106 of FIGs. lA and 1B, which has an asymmetric shape. Both input 220 and output 224 faces of the reflector 206 are shown disposed at Brewster's angle with respect to the impinging laser beam 110, the output face 224 being substantially parallel to the slow divergence axis 116 (FIG. 1C) of the laser beam 110. The reflector 206 may further include a TIR first reflector surface 221 disposed at an acute angle to the mount 102. The acute angle is set based on the angles of refraction of the laser beam 110 into and out of the reflector 206. The input 220 and output 224 faces may form obtuse angles with the TIR first reflector face 221. The input face 220 and the output face 224 may form the same obtuse angle to the first reflector face 221, with the four face side of the reflector 206 taking any form, including parallel to the first reflector face 221 forming a trapezoidal prism.

Due to Brewster's angles of incidence and reflection by TIR, the reflector 206 needs not be coated with an optical coating. This may significantly reduce manufacturing costs of the reflector 206, especially when the reflector 206 is manufactured in large quantities by injection molding using a suitable transparent material, such as an optical-grade plastic or a low-temperature glass.

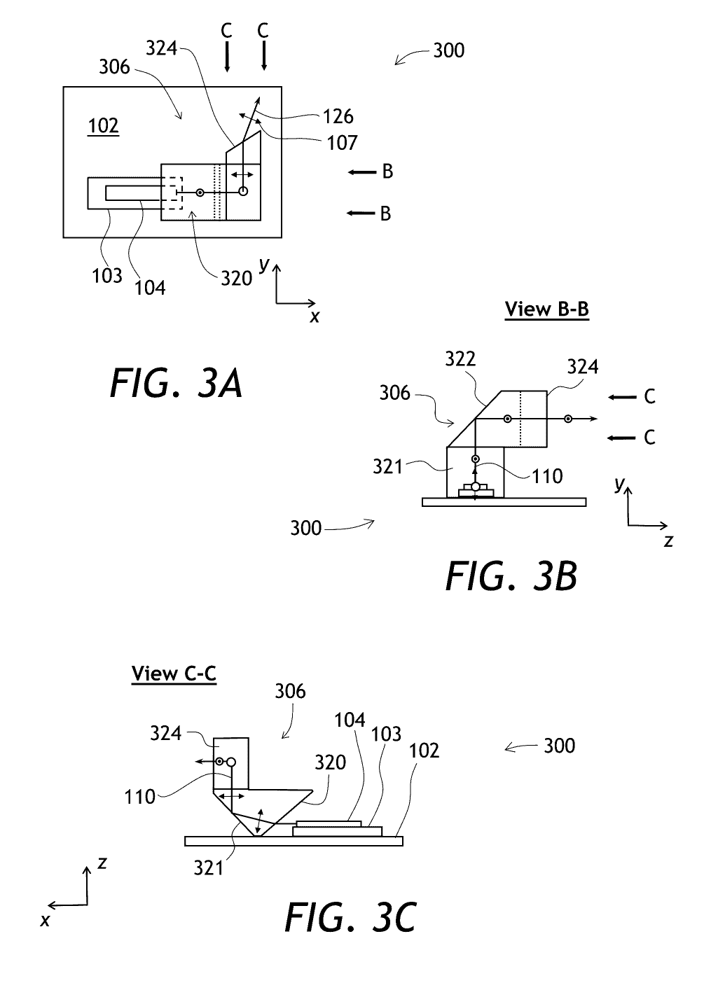

Referring to FIGS. 3A, 3B, and 3C with further reference to FIGS. 1A-1C, a laser diode assembly 300 of FIGS. 3A-3C is an embodiment of the laser diode assembly 100 of FIG. lA and 1B. The laser diode assembly 300 of FIGS. 3A-3C may include a reflector 306 having a shape defined by input face 320, first 321 and second 322 reflector faces, and an output face 324. The first reflector face 321 may be disposed to reflect the laser beam 110 impinging on the first reflector face 321 by TIR, as defined by condition (1), in a direction away and upwards from the mount 102, for example in XZ plane as shown. The second reflector face 322 may be disposed in the optical path 126 of the laser beam 110 between the first reflector face 321 and the output face 324, for reflecting the laser beam 110 impinging on the second reflector face 322 by TIR, as defined by condition (1) above. The input 320 and output 324 faces may be disposed at Brewster's angle with respect to the impinging laser beam 110, as defined by condition (2) above. The resulting shape of the reflector 306 may include a plurality of prismatic or pyramidal-shape elements extending from one another, for example: a compound prism comprising a first triangular prism, including the input 310 and first reflector faces 321 for directing the laser beam 110 upwardly and away from the mount 102, e.g. perpendicular thereto; a second triangular prism, including the second reflector face 322 disposed at an acute angle to the laser beam 110 for redirecting the laser beam 110 parallel but spaced apart from the mount 102; and a third triangular or trapezoidal prism, including the output face 324.

As may be seen in FIGS. 3A and 3B, the second reflector face 322 may redirect the laser beam 110 to propagate in XY plane, that is, parallel to the base 102 and to the bottom 105 of the laser diode chip 104. In FIG. 3C, the plane of incidence of the optical beam 110 onto the first reflector 321 is the XZ plane. In FIG. 3B, the plane of incidence of the laser beam 110 onto the second reflector 322 is the YZ plane. Thus, the first 321 and second reflector 322 faces are disposed so that planes of incidence of the laser beam 110 on the first 321 and second 322 reflector faces are substantially perpendicular to each other. Such position of the first 321 and second 322 reflector faces may enable rotation of the laser beam 110 about the direction of propagation 112, so that the orientation of the fast 114 and slow 116 axes (FIG. 1C) may be switched.

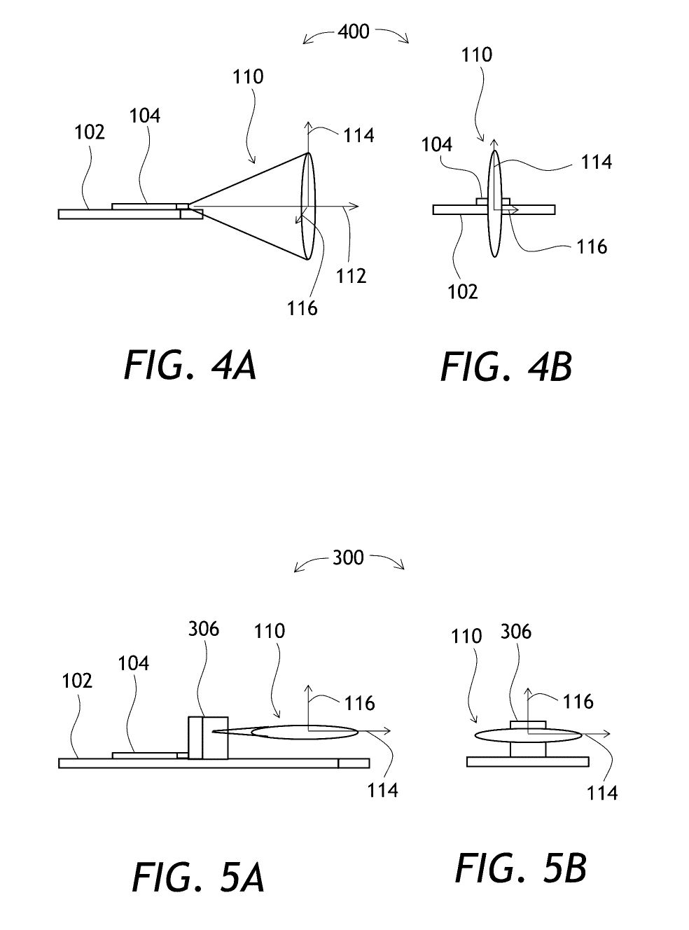

Referring now to FIGS. 4A, 4B, 5A, and 5B, the rotation of the laser beam 110 by the first 321 and second 322 reflector faces of the reflector 306 (FIGS. 3A-3C) is further illustrated. In FIGS. 4A and 4B, the laser beam 110 emitted by the laser diode chip 104 of an example laser diode assembly 400 has the fast axis 114 perpendicular to the mount 102. In FIGS. 5A and 5B, the reflector 306 of the laser diode assembly 300 rotates the laser beam 110 about the direction of propagation 112, so that the fast axis 114 is parallel to the mount 102. As a result of the rotation of the laser beam 110 about the direction of propagation 112 by the first 321 and second reflector 322 faces of the reflector 306, the rotated laser beam 110 does not get clipped by the mount 102 as the laser beam 110 propagates above and parallel to the mount 102 (FIGS. 5A and 5B).

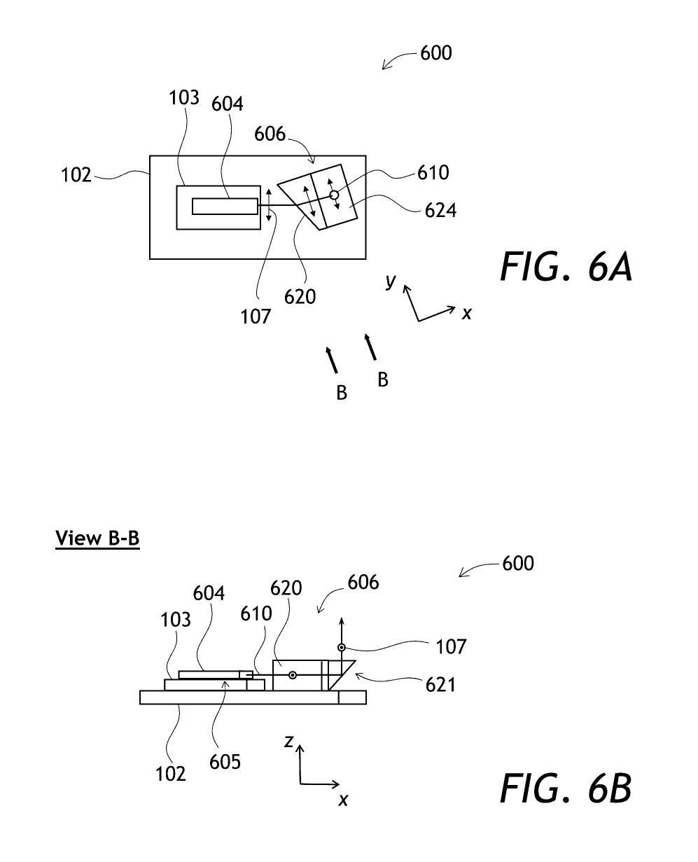

Turning to FIGS. 6A and 6B with further reference to FIGS. 1A-1C, a laser diode assembly 600 is a variant of the laser diode assembly 100 of FIGS. 1A and 1B. A laser diode chip 604 of the laser diode assembly 600 of FIGS. 6A and 6B emits a horizontally polarized laser beam 610, as denoted with the arrows 107. In other words, the laser beam 610 is polarized in XY plane, which is parallel to a bottom surface 605 of the laser diode chip 604. Yet the fast 114 and slow 116 divergence axes of the horizontally polarized laser beam 610 are oriented in the same way as the fast 114 and slow 116 divergence axes of the laser beam 110 shown in FIG. 1C.

A reflector 606 of the laser diode assembly 600 of FIGS. 6A and 6B may include an input face 620, a first reflector face 621, and an output face 624. The input face 620 may be disposed at Brewster's angle as given by Condition (2) above, and substantially parallel to the fast divergence axis 114 of the laser beam 610 impinging on the input face 620. Since the laser beam 610 is horizontally polarized, the laser beam 610 is p-polarized with respect to the input face 620, so that a transmission loss of the laser beam 610 may be lessened. The first reflector face 621 may reflect the laser beam 610 by TIR, as represented by Condition (1) above. The overall shape of the reflector 606 may be defined by the position and orientation of the input face 620, the first reflector face 621, and the output face 624. For example, the reflector 606 may include a pair of prismatic elements extending from one another, as shown in FIGS. 6A and 6B: a compound prism comprising a first triangular prism, including the input face 620; and a second triangular prism, including the first reflector face 621 for directing the laser beam 110 upwardly and away from the mount 102, e.g. perpendicular thereto and the output face 624. The output face 624 is shown in FIG. 6B nearly perpendicular to the laser beam 610. To reduce transmission losses, the output face 624 may be coated with an AR coating, or disposed at Brewster's angle as represented by Condition (2) above.

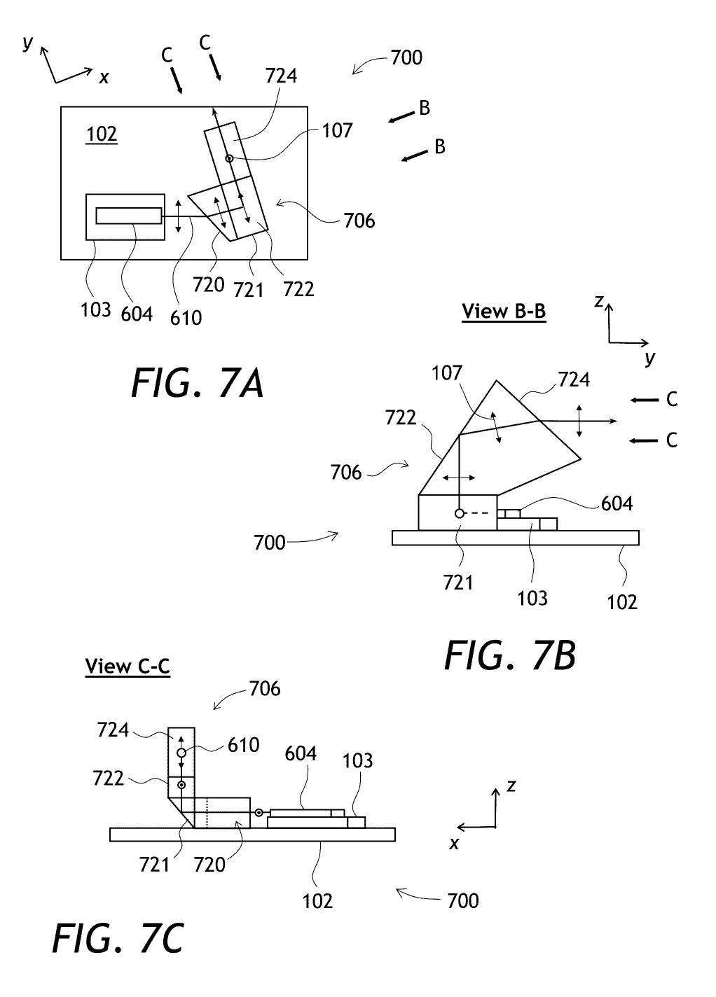

Referring now to FIGS. 7A, 7B, and 7C with further reference to FIGS. 6A and 6B, a laser diode assembly 700 is a variant of the laser diode assembly 600 of FIGS. 6A and 6B. The laser diode assembly 700 of FIGS. 7A-7C may include a reflector 706 having an input face 720, first 721 and second 722 reflector faces, and an output face 724. Both the input 720 and output 724 faces of the reflector 706 may be disposed at Brewster's angle (Condition (2)) with respect to the impinging laser beam 610. Both the first 721 and second 722 reflector faces of the reflector 706 may be disposed for reflecting the impinging laser beam 610 by TIR (Condition (1)). Together, the input 720 and output 724 faces and the first 721 and second 722 reflector faces define an overall shape of the reflector 706, which may include a plurality of prismatic or pyramidal elements extending from one another, for example: a compound prism comprising a first triangular prism, including the input face 720; a second triangular prism, including the first reflector face 721 disposed at an acute angle to the laser beam 110 for directing the laser beam 110 upwardly and away from the mount 102, e.g. perpendicular thereto; and a third triangular or trapezoidal prism, including the second reflector surface 722 for redirecting the laser beam 110 parallel but spaced apart from the mount 102, and the output face 724. Due to the usage of TIR and Brewster's surfaces the reflector 706 may not require any optical coatings.

The reflector 706 may operate to rotate the laser beam 610 about its optical axis by 90°, so as to substantially swap, or switch, the fast 114 and slow 116 divergence axes, as explained above with reference to FIGS. 4A, B and 5A, B. The output beam 610 may propagate in XY plane, that is, parallel to the bottom surface 605 of the laser diode chip 604, or parallel to the mount 102 and the submount 103.

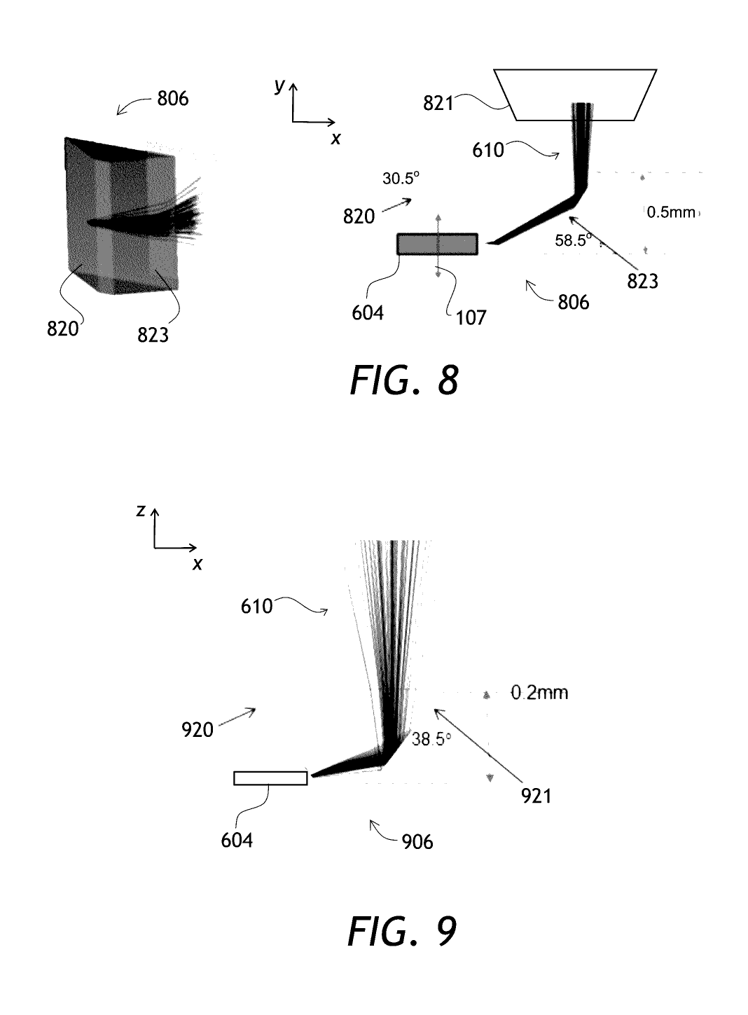

Referring to FIG. 8 with further reference to FIGS. 6A and 6B, a prismatic reflector 806 is a variant of the reflector 606 of FIGS. 6A and 6B. The prismatic reflector 806 of FIG. 8 may include an input Brewster face 820 for transmitting the optical beam 610 impinging on the input Brewster face 820, and a reflector face 823 disposed perpendicular to the XY plane for reflecting, by TIR, the optical beam 610 transmitted through the input face 820. The input face 820 and the reflector face 823 form almost 90 degrees angle. The prismatic reflector 806 may turn the optical beam 610 by 90° in XY plane, that is, in the plane of the laser diode chip 604. An additional TIR reflector face 821 may be provided for reflecting the laser beam 610 upwards, for propagation along the Z axis (perpendicular to the plane of FIG. 8), similarly to the first reflector face 621 of the reflector 606 of FIGS. 6A and 6B.

Turning to FIG. 9 with further reference to FIGS. 6A and 6B, a prismatic reflector 906 may be used for redirecting the laser beam 610 vertically. To that end, the prismatic reflector 900 may include an input face 920 and a TIR reflector face 921, which is similar to the first reflector face 621 of the reflector 606 of FIGS. 6A and 6B. The prismatic reflector 906 may be symmetric, have an angle between the input face 920 and the reflector face 921 of 77° and have a height of only 0.2 mm. Of course, the dimensions are only meant as an example. The input face 920 is preferably AR coated, because it is not at a Brewster's angle with respect to the impinging laser beam 610.

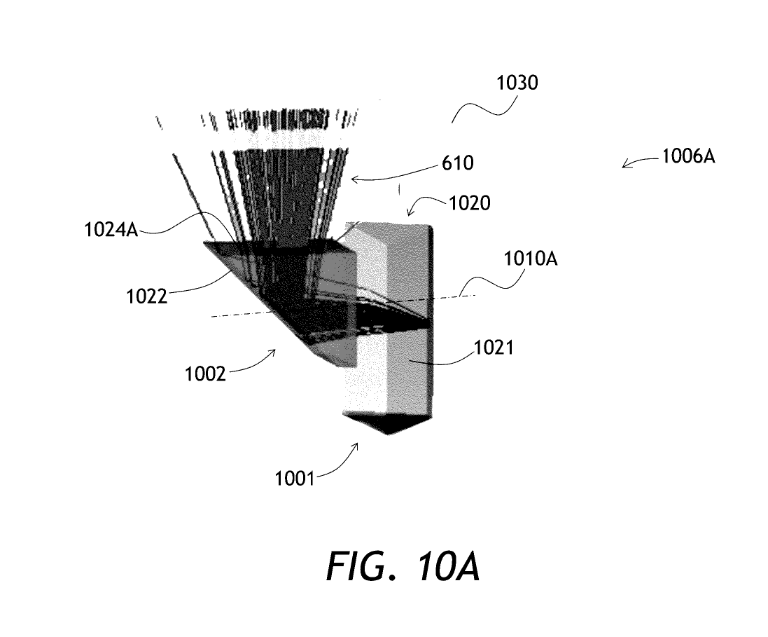

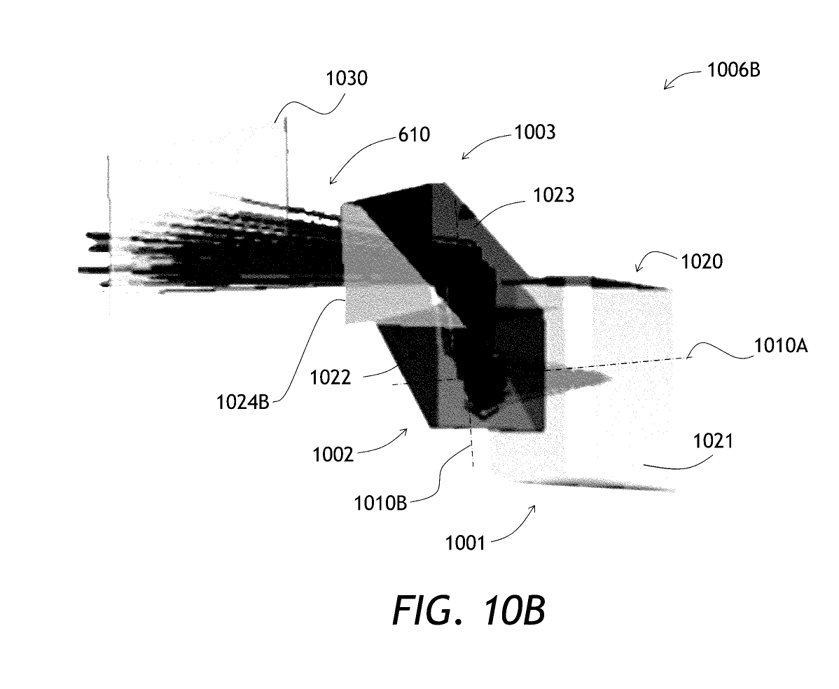

Referring to FIG. 10A with further reference to FIGS. 8 and 9, a reflector 1006A may include two prismatic reflector segments, one similar to the prismatic reflector 806 of FIG. 8 and the other similar to the prismatic reflector 906 of FIG. 9. More specifically, the reflector 1006 may include a first prismatic segment 1001 comprising an input Brewster face 1020 for transmitting the impinging laser beam 610, and a first reflector face 1021 for reflecting, by TIR, the laser beam 610 transmitted through the input face 1020. A second prismatic segment 1002 may extend from the first prismatic segment 1001. The first 1001 and second 1002 segments are shown in FIG. 10A spatially separated for clarity only. The second prismatic segment 1002 may include a second reflector face 1022 for reflecting, by TIR, the laser beam 610 reflected from the first reflector face 1021, and an output face 1024A for transmitting the laser beam 610 reflected from the second reflector face 1221. The output face 1024A may be disposed at a Brewster's angle with respect to the impinging laser beam 610. In FIG. 10A, the second prismatic segment 1002 forms a substantially 90° rotation angle with respect to the first prismatic segment 1002 about an optical axis 1010A between the first 1021 and second 1022 reflector faces. The laser beam 610 exiting the output face 1224A of the second prismatic segment 1002 propagates vertically. In FIG. 10A, the exiting laser beam 610 is shown impinging on an image surface 1030, which was used in computer simulations as an end surface.

In comparison with the reflector 606 of FIGS. 6A and 6B, the reflector 1006A of FIG. 10A further includes an extra reflector face, specifically the first reflector face 1021, disposed in the optical path of the laser beam 610 between the input face 620 and the first reflector 621 of the reflector 606 of FIGS. 6A and 6B. This extra TIR reflector face may be needed to turn the laser beam 610 by an additional angle, as required, since the TIR Condition (1) may not provide a sufficient angle of turn by a single TIR reflection. More TIR reflector faces may be provided as needed.

Turning now to FIG. 10B with further reference to FIG. 10A, a reflector 1006B may include the reflector 1006A of FIG. 10A and a third prismatic segment 1003 extending from the second prismatic segment 1002. The third prismatic segment 1003 may include a third reflector face 1023 for reflecting, by TIR, the laser beam 610 reflected from the second reflector face 1022, and an output face 1024B for transmitting the laser beam 610 reflected from the third reflector face 1023. In FIG. 10B, the third prismatic segment 1003 forms a 90° rotation angle with respect to the second prismatic segment 1002 about an optical axis 1010B between the second 1002 and third 1003 reflector faces.

In comparison with the reflector 706 of FIGS. 7A-7C, the reflector 1006B of FIG. 10B further includes an extra reflector face, specifically the first reflector face 1021, disposed in the optical path of the laser beam 610 between the input face 620 and the first reflector 721 of the reflector 706 of FIGS. 7A and 7B. This extra TIR reflector face, or more than one extra TIR reflector face, may be needed to turn the laser beam 610 by an additional angle, as required. One advantage of the reflectors 206; 306; 606; 706; 806; and 1006A, 1006B is that these reflectors may be inexpensively manufactured out of a suitable transparent plastic material with millimeter-size dimensions, for example 10 mm×10 mm×10 mm or smaller.

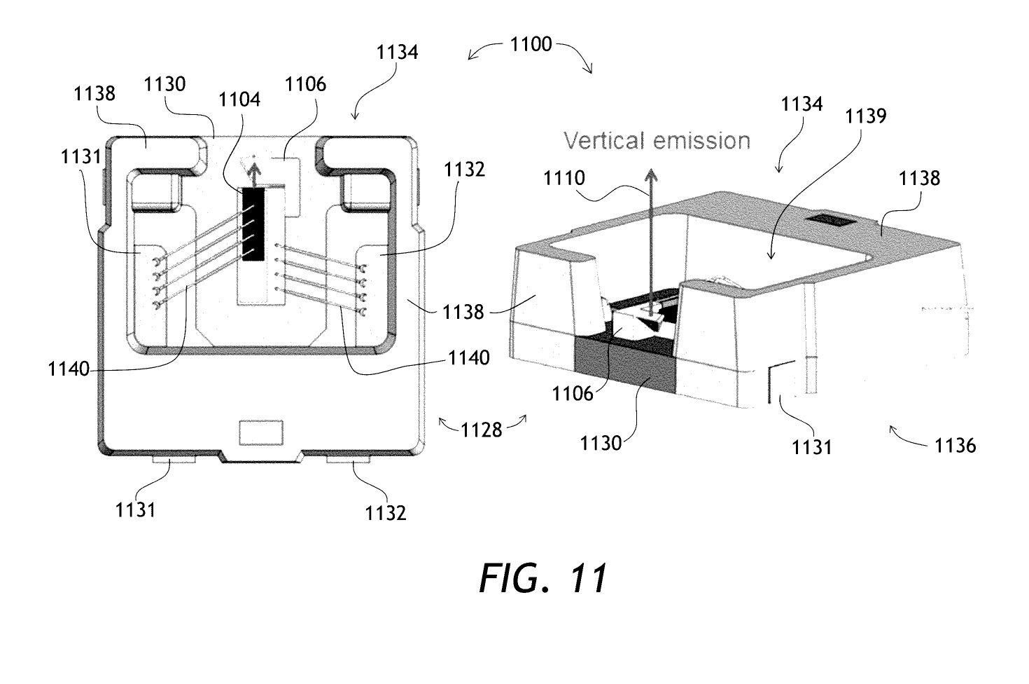

Referring to FIG. 11, a packaged laser diode assembly 1100 may include a leadframe 1128 comprising a thermally and electrically conductive floor plate 1130, first 1131 and second 1132 electrodes, and a plastic framework 1134 supporting the floor plate 1130, the first electrode 1131, and the second electrode 1132. The plastic framework 1124 may electrically insulate the floor plate 1130, the first electrode 1131, and the second electrode 1132 from each other. The plastic framework 1134 may include a bottom portion 1136 having therein or thereon the floor plate 1130. The bottom portion 1136 may have a sidewall 1138 extending from the bottom portion 1136 on its perimeter, thereby defining a protective compartment space 1139 with the floor plate 1130 at the bottom. Other type packages may also be provided.

A laser diode chip 1104 may be mounted on the floor plate 1130, coupled with wirebonds 1140 to the first 1131 and second 1132 electrodes, and at least partially disposed within the protective compartment space 1139. A reflector 1106 may be mounted on the floor plate 1130 for redirecting a laser beam 1110 upwards as shown. The reflector 1106 may be any one of the reflectors 206; 306; 606; 706; 806; and 1006A, 1006B described above.

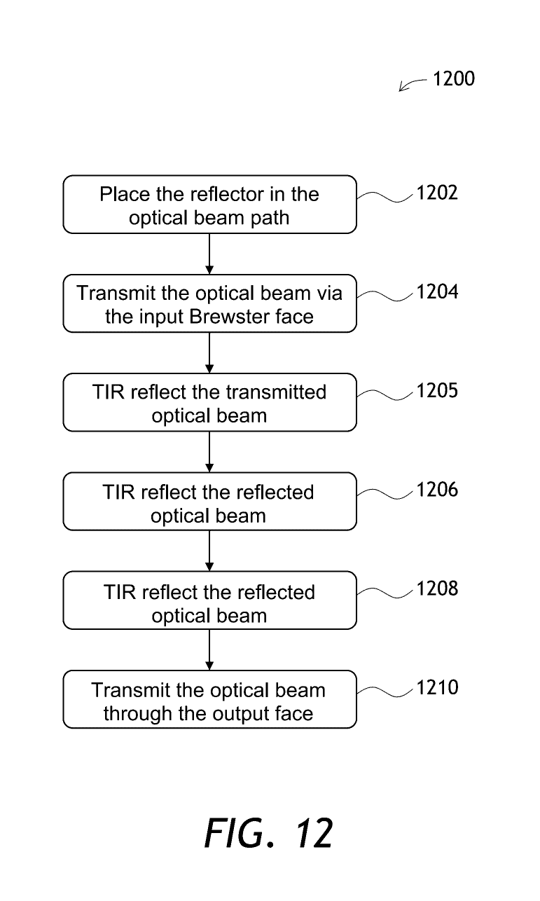

Referring now to FIG. 12, a method 1200 for directing an optical beam, for example the laser beam 110 of FIGS. 1A-1C, the laser beam 610 of FIGS. 6A 6B, or the laser beam 1110 of FIG. 11 emitted by an edge-emitting laser chip, for example the laser diode chip 104, the laser diode 604, or the laser diode 1104, may include a step 1202 of disposing in an optical path of the optical beam a reflector, for example any one of the reflectors 206; 306; 606; 706; 806; and 1006A, 1006B described above, including an input face, a first TIR reflector face, a second TIR reflector face, and an output face for transmitting the impinging optical beam.

In a first transmitting step 1204, the optical beam may be transmitted through the input face at Brewster's angle defined by the Condition (2) above. In a first reflecting step 1206, the optical beam transmitted through the input face may be reflected with the first reflector face. Preferably, the reflection is by TIR as defined by Condition (1) above.

In a second reflecting step 1208, the optical beam reflected from the first reflector face may be reflected, by TIR, with the second reflector face. In a second transmitting step 1210, the optical beam reflected from the second reflector face may be transmitted through the output face. As explained above, the second reflector face may be disposed with respect to the first reflector face so that planes of incidence of the optical beam on the first and second reflector faces are substantially perpendicular to each other. In an embodiment where the reflector includes a third reflector face, the method may include a third reflecting step 1205 of reflecting, by TIR, the optical beam transmitted through the input face with the third reflector face, to redirect the optical beam to the first reflector face.

The present disclosure is not to be limited in scope by the specific embodiments described herein. Indeed, other various embodiments and modifications, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A laser diode assembly comprising:
a mount;
a laser diode chip comprising a bottom surface on the mount, an end facet for emitting a laser beam comprising a direction of propagation, a fast divergence axis, and a slow divergence axis, mutually perpendicular to each other;
a reflector on the mount, for receiving and redirecting the laser beam, the reflector comprising an input face, a first reflector face, and an output face disposed consecutively in an optical path of the laser beam, wherein the optical path is defined by orientation of the input face, the first reflector face, and the output face;
wherein at least one of the input and output faces is disposed at a Brewster's angle with respect to the laser beam for transmitting the laser beam;
wherein the first reflector face is disposed for receiving the laser beam transmitted through the first face and for reflecting the laser beam by total internal reflection; and
wherein the output face is configured to transmit the laser beam reflected from the first reflector face in a direction substantially orthogonal to a direction of laser beam when the laser beam is emitted from the end facet.

2. The laser diode assembly of claim 1, wherein the input face is disposed at a Brewster's angle with respect to the laser beam impinging thereon.

3. The laser diode assembly of claim 2, wherein the input face is substantially parallel to the fast divergence axis of the laser beam impinging thereon.

4. The laser diode assembly of claim 1, wherein the output face is disposed at a Brewster's angle with respect to the laser beam impinging thereon.

5. The laser diode assembly of claim 4, wherein the output face is substantially parallel to the slow divergence axis of the laser beam impinging thereon.

6. The laser diode assembly of claim 1, wherein the input face, the first reflector face, and the output face are disposed such that the laser beam exiting from the output face forms a 90° angle with the laser beam impinging on the input face.

7. The laser diode assembly of claim 1, wherein the input face, the first reflector face, the output face, and the bottom surface of the laser diode chip are disposed perpendicular to a same plane.

8. The laser diode assembly of claim 1, wherein the first reflector face is disposed to reflect the laser beam impinging thereon in a direction away and upwards from the mount, and the laser diode assembly further comprises:
a second reflector face disposed in the optical path of the laser beam between the first reflector face and the output face, for reflecting the laser beam impinging on the second reflector face by total internal reflection.

9. The laser diode assembly of claim 8, wherein the output face is disposed at a Brewster's angle with respect to the laser beam impinging thereon.

10. The laser diode assembly of claim 8, wherein the first and second reflector faces are disposed so that planes of incidence of the laser beam on the first and second reflector faces are substantially perpendicular to each other.

11. The laser diode assembly of claim 8, wherein the second reflector face is oriented to reflect the laser beam to propagate substantially parallel to the bottom surface of the laser diode chip.

12. The laser diode assembly of claim 11, wherein the second reflector face and the output face are oriented so that the fast axis of the laser beam exiting the output face is substantially parallel to the bottom surface of the laser diode chip.

13. The laser diode assembly of claim 8, wherein the reflector further comprises a third reflector face disposed in the optical path of the laser beam between the input face and the first reflector, for reflecting the laser beam impinging on the third reflector face by total internal reflection.

14. The laser diode assembly of claim 1, wherein the reflector comprises a plastic material substantially transparent to the laser beam.

15. A reflector comprising:
a first prismatic segment comprising an input Brewster face for transmitting an optical beam impinging thereon, and a first reflector face for reflecting, by total internal reflection, the optical beam transmitted through the input face; and
a second prismatic segment extending from the first prismatic segment, the second prismatic segment comprising a second reflector face for reflecting, by total internal reflection, the optical beam reflected from the first reflector face;
wherein the second prismatic segment forms a 90° rotation angle with respect to the first prismatic segment about an optical axis between the first and second reflector faces, and
wherein the reflected optical beam is transmitted in a direction substantially orthogonal to a direction of the optical beam when the optical beam impinges the first prismatic segment.

16. The reflector of claim 15, wherein the second prismatic segment further comprises an output face disposed at a Brewster's angle with respect to the optical beam impinging thereon.

17. The reflector of claim 15, further comprising:
a third prismatic segment extending from the second prismatic segment, the third prismatic segment comprising a third reflector face for reflecting, by total internal reflection, the optical beam reflected from the second reflector face, and an output face for transmitting the optical beam reflected from the third reflector face;
wherein the third prismatic segment forms a 90° rotation angle with respect to the second prismatic segment about an optical axis between the second and third reflector faces.

18. The reflector of claim 15, comprising a transparent plastic material comprising dimensions of no greater than 20 mm×20 mm×10 mm.

19. A method for directing an optical beam emitted by an edge-emitting laser diode chip, the method comprising:
disposing in an optical path of the optical beam a reflector comprising an input Brewster face for transmitting the optical beam impinging thereon, a first reflector face, a second reflector face, and an output face for transmitting the optical beam reflected from the second reflector face, wherein the second reflector face is disposed with respect to the first reflector face so that planes of incidence of the optical beam on the first and second reflector faces are substantially perpendicular to each other;
transmitting the optical beam through the input Brewster face;
reflecting, by total internal reflection, the optical beam transmitted through the input face with the first reflector face;
reflecting, by total internal reflection, the optical beam reflected from the first reflector face with the second reflector face; and
transmitting the optical beam reflected from the second reflector face through the output face,
wherein the optical beam is transmitted in a direction substantially orthogonal to a direction of optical beam when the optical beam is emitted from the edge-emitting laser diode chip.

20. The method of claim 19, wherein
the reflector further comprises a third reflector face, and
the method further comprises:
reflecting, by total internal reflection, the optical beam transmitted through the input face with the third reflector face, to redirect the optical beam to the first reflector face.
